(19) United States
(12) Patent Application Publication
(10) Pub. No.: US 2022/0278504 A1
(43) Pub. Date: Sep. 1, 2022

(54) LIGHT EMITTING APPARATUS AND PROJECTOR

(71) Applicants: SEIKO EPSON CORPORATION, Tokyo (JP); SOPHIA SCHOOL CORPORATION, Tokyo (JP)

(72) Inventors: Takuya YOSHIMOTO, SHIOJIRI SHI (JP); Katsumi KISHINO, TOKYO TO (JP)

(73) Assignees: SEIKO EPSON CORPORATION, Tokyo (JP); SOPHIA SCHOOL CORPORATION, Tokyo (JP)

(21) Appl. No.: 17/679,059

(22) Filed: Feb. 23, 2022

(30) Foreign Application Priority Data
Feb. 26, 2021 (JP) 2021-030043

(51) Int. Cl. H01S 5/11; H01S 5/183; G03B 21/20

(52) U.S. Cl. CPC H01S 5/11; H01S 5/18308; G03B 21/2033

(57) ABSTRACT

A light emitting apparatus includes a substrate and a laminated structure provided at a substrate surface of the substrate and including a plurality of columnar sections. The columnar sections each include a light emitting layer which has a first end facing the substrate and a second end facing away from the substrate. A first cross section of each of the columnar sections taken along the directions perpendicular to the lamination direction of the laminated structure includes the first end. A second cross section of each of the columnar sections taken along the directions perpendicular to the lamination direction is a cross section that is part of the light emitting layer and located at a position shifted from the first cross section toward the side away from the substrate in the lamination direction. In the plan view viewed in the lamination direction, the position of the center of the first cross section differs from the position of the center of the second cross section.

### CROSS-REFERENCE TO RELATED APPLICATIONS

The present application is based on, and claims priority from JP Application Serial Number 2021-030043, filed Feb. 26, 2021, the disclosure of which is hereby incorporated by reference herein in its entirety.

### BACKGROUND

### 1. Technical Field

The present disclosure relates to a light emitting apparatus and a projector.

### 2. Related Art

Semiconductor lasers are expected as a high-luminance, next-generation light source. Among the semiconductor lasers, those using nanocolumns are expected to achieve high power light emission at small radiation angles based on the photonic crystal effect provided by the nanocolumns.

For example, JP-A-2018-142660 describes an optical device including a plurality of columnar crystals made of a group III-V semiconductor and each including an active layer.

It is desired that optical devices, such as that described above, output light having increased intensities.

### SUMMARY

A light emitting apparatus according to an aspect of the present disclosure includes a substrate and a laminated structure provided at a substrate surface of the substrate and including a plurality of columnar sections. The columnar sections each include a light emitting layer. The light emitting layer has a first end facing the substrate and a second end facing away from the substrate. A first cross section of each of the columnar sections taken along directions perpendicular to a lamination direction of the laminated structure includes the first end. A second cross section of each of the columnar sections taken along the directions perpendicular to the lamination direction is a cross section that is part of the light emitting layer and located at a position shifted from the first cross section toward the side away from the substrate in the lamination direction. In a plan view viewed in the lamination direction, a position of a center of the first cross section differs from a position of a center of the second cross section.

A projector according to another aspect of the present disclosure includes the light emitting apparatus according to the aspect of the present disclosure.

### BRIEF DESCRIPTION OF THE DRAWINGS

FIG. 1 is a cross-sectional view diagrammatically showing a light emitting apparatus according to an embodiment of the present disclosure.

FIG. 2 is a cross-sectional view diagrammatically showing a columnar section of the light emitting apparatus according to the embodiment.

FIG. 3 diagrammatically shows cross sections of the columnar section of the light emitting apparatus according to the embodiment.

FIG. 4 is a cross-sectional view diagrammatically showing one of the steps of manufacturing the light emitting apparatus according to the embodiment.

FIG. 5 is a cross-sectional view diagrammatically showing one of the steps of manufacturing the light emitting apparatus according to the embodiment.

FIG. 6 is a perspective view diagrammatically showing one of the steps of manufacturing the light emitting apparatus according to the embodiment.

FIG. 7 is a cross-sectional view diagrammatically showing one of the steps of manufacturing the light emitting apparatus according to the embodiment.

FIG. 8 diagrammatically shows a projector according to the embodiment.

FIG. 9 shows a cross-sectional TEM image of columnar sections.

### DESCRIPTION OF EXEMPLARY EMBODIMENTS

A preferable embodiment of the present disclosure will be described below in detail with reference to the drawings. It is not intended that the embodiment described below unduly limits the contents of the present disclosure described in the claims. Furthermore, all configurations described below are not necessarily essential configuration requirements of the present disclosure.

### 1. Light Emitting Apparatus

### 1.1. Overall Configuration

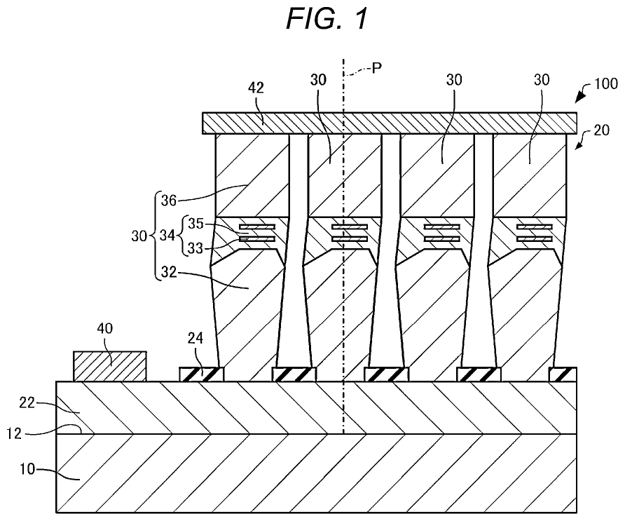

A light emitting apparatus according to the present embodiment will first be described with reference to the drawings. FIG. 1 is a cross-sectional view diagrammatically showing a light emitting apparatus 100 according to the present embodiment.

The light emitting apparatus 100 includes, for example, a substrate 10, a laminated structure 20, a first electrode 40, and a second electrode 42, as shown in FIG. 1. The light emitting apparatus 100 is a semiconductor laser.

The substrate 10 is, for example, an Si substrate, a GaN substrate, a sapphire substrate, or an SiC substrate. The substrate 10 has a substrate surface 12. In illustrated example, the substrate surface 12 is the upper surface of the substrate 10. The substrate surface 12 has a perpendicular P.

The laminated structure 20 is provided at the substrate surface 12 of the substrate 10. In the illustrated example, the laminated structure 20 is provided on the substrate 10. The laminated structure 20 includes, for example, a buffer layer 22 and columnar sections 30.

The present specification will be described on the assumption that in a lamination direction of the laminated structure 20 (hereinafter also simply referred to as “lamination direction”), the direction from light emitting layers 34, which serve as a reference, toward second semiconductor layers 36 is called an “upward direction” and the direction from the light emitting layers 34 toward first semiconductor layers 32 is called a “downward direction”. The directions perpendicular to the lamination direction are also called “in-plane directions”. The “lamination direction of the laminated structure 20” refers to the direction in which the first semiconductor layer 32 and the light emitting layer 34 of each of the columnar sections 30 are laminated structured on each other. The direction of the perpendicular P is the lamination direction.

The buffer layer 22 is provided on the substrate 10. The buffer layer 22 is, for example, an n-type GaN layer having been doped with Si. A mask layer 24 for forming the columnar sections 30 is provided on the buffer layer 22. The mask layer 24 is, for example, a silicon oxide layer, a titanium layer, a titanium oxide layer, or an aluminum oxide layer.

The columnar sections 30 are provided on the buffer layer 22. The columnar sections 30 each have a columnar shape protruding upward beyond the buffer layer 22. In other words, the columnar sections 30 protrude upward from the substrate 10 through the buffer layer 22. The columnar sections 30 are also called, for example, nanocolumns, nanowires, nanorods, and nanopillars. The columnar sections 30 each have, for example, a polygonal or circular planar shape.

The columnar sections 30 each have a diameter, for example, greater than or equal to 50 nm but smaller than or equal to 500 nm. When the diameter of each of the columnar sections 30 is smaller than or equal to 500 nm, a high-quality-crystal light emitting layer 34 can be produced, and distortion intrinsically present in the light emitting layer 34 can be reduced. The light generated in the light emitting layer 34 can thus be efficiently amplified.

In a case where the columnar sections 30 each have a circular planar shape, the term “the diameter of each of the columnar sections” refers to the diameter of the circular shape, and in a case where the columnar sections 30 each have a non-circular planar shape, the term refers to the diameter of a minimum circle containing the non-circular shape therein. For example, in a case where the columnar sections 30 each have a polygonal planar shape, the diameter of each of the columnar sections 30 is the diameter of a minimum circle containing the polygonal shape therein, and in a case where the columnar sections 30 each have an elliptical planar shape, the diameter of each of the columnar sections 30 is the diameter of a minimum circle containing the elliptical shape therein.

The plurality of columnar sections 30 are provided. The distance between adjacent columnar sections 30 is, for example, greater than or equal to 1 nm but smaller than or equal to 500 nm. The plurality of columnar sections 30 are arranged in a predetermined direction at predetermined intervals in the plan view viewed in the lamination direction. The plurality of columnar sections 30 are arranged, for example, in a triangular or square lattice. The plurality of columnar sections 30 can provide the photonic crystal effect.

The “interval between the columnar sections” is the distance between the centers of columnar sections 30 adjacent to each other in any of the predetermined direction. In the case where the columnar sections 30 each have a circular planar shape, the term “the center of each of the columnar sections” refers to the center of the circle, and in the case where the columnar sections 30 each have a non-circular planar shape, the term refers to the center of the minimum circle containing the non-circular shape therein. For example, in the case where the columnar sections 30 each have a polygonal planar shape, the center of each of the columnar sections 30 is the center of a minimum circle containing the polygonal shape therein, and in the case where the columnar sections 30 each have an elliptical planar shape, the center of each of the columnar sections is the center of a minimum circle containing the elliptical shape therein.

In the case where the columnar sections 30 each have a circular planar shape, the term “the center of a cross section of each of the columnar sections” refers to the center of the circle, and in the case where the columnar sections 30 each have a non-circular planar shape, the term refers to the center of the minimum circle containing the non-circular shape therein in the plan view viewed in the lamination direction. For example, in a case where the columnar sections 30 each have a polygonal cross-sectional shape, the center of a cross section of each of the columnar sections 30 is the center of a minimum circle containing the polygonal shape therein, and in a case where the columnar sections 30 each have an elliptical cross-sectional shape, the center of a cross section of each of the columnar sections 30 is the center of a minimum circle containing the elliptical shape therein.

The columnar sections 30 each include the first semiconductor layer 32, the light emitting layer 34, and the second semiconductor layer 36. The detailed shape and other factors of each of the columnar sections 30 will be described later.

The first semiconductor layer 32 is provided on the buffer layer 22. The first semiconductor layer 32 is provided between the substrate 10 and the light emitting layer 34. The first semiconductor layer 32 is, for example, an n-type GaN layer having been doped with Si.

The light emitting layer 34 is provided on the first semiconductor layers 32. The light emitting layer 34 is provided between the first semiconductor layer 32 and the second semiconductor layer 36. The light emitting layer 34 generates light when current is injected thereinto. The light emitting layer 34 includes, for example, well layers 33 and barrier layers 35. The well layers 33 and the barrier layers 35 are each an i-type semiconductor layer having been intentionally doped with no impurities. The well layers 33 are each, for example, an InGaN layer. The barrier layers 35 are each, for example, a GaN layer. The light emitting layer 34 has a multiple quantum well (MQW) structure formed of the well layers 33 and the barrier layers 35.

The numbers of well layers 33 and barrier layers 35, which form the light emitting layer 34, are not each limited to a specific number. For example, only one well layer 33 may be provided, and the light emitting layer 34, in this case, has a single quantum well (SQW) structure.

The second semiconductor layer 36 is provided on the light emitting layer 34. The second semiconductor layer 36 is a layer different from the first semiconductor layer 32 in terms of conductivity type. The second semiconductor layer 36 is, for example, a p-type GaN layer having been doped with Mg. The first semiconductor layer 32 and the second semiconductor layer 36 form a cladding layer having the function of confining the light in the light emitting layer 34.

Although not illustrated, an optical confinement layer (OCL) formed of an i-type InGaN layer may be provided between the first semiconductor layer 32 and the light emitting layer 34. The second semiconductor layer 36 may include an electron blocking layer (EBL) formed of a p-type AlGaN layer.

In the light emitting apparatus 100, the p-type second semiconductor layers 36, the i-type light emitting layers 34, which have been doped with no impurities, and the n-type first semiconductor layers 32 form pin diodes. In the light emitting apparatus 100, when a forward bias voltage for the pin diodes is applied to the space between the first electrode 40 and the second electrode 42, current is injected into the light emitting layers 34, whereby the electrons and holes recombine with each other in the light emitting layers 34. The recombination causes light emission. The light generated in the light emitting layers 34 propagates in the in-plane directions and forms a standing wave because of the photonic crystal effect provided by the plurality of columnar sections 30, and the standing wave receives gain in the light emitting layers 34 to undergo laser oscillation. The light emitting apparatus 100 then emits positive first order diffracted light and negative first order diffracted light as laser light in the lamination direction.

Although not illustrated, a reflection layer may be provided between the substrate 10 and the buffer layer 22 or below the substrate 10. The reflection layer is, for example, a distributed Bragg reflector (DBR) layer. The reflection layer can reflect the light generated in the light emitting layers 34, whereby the light emitting apparatus 100 can emit the light only via the side facing the second electrode 42.

The first electrode 40 is provided on the buffer layer 22. The buffer layer 22 may be in ohmic contact with the first electrode 40. The first electrode 40 is electrically coupled to the first semiconductor layers 32. In the illustrated example, the first electrode 40 is electrically coupled to the first semiconductor layers 32 via the buffer layer 22. The first electrode 40 is one of the electrodes for injecting the current into the light emitting layers 34. The first electrode 40 is, for example, a laminated structure of a Cr layer, an Ni layer, and an Au layer laminated structured on each other in the presented order from the side facing the buffer layer 22.

The second electrode 42 is provided on the second semiconductor layers 36. The second electrode 42 is provided on the opposite side of the laminated structure 20 from the substrate 10. The second electrode 42 is electrically coupled to the second semiconductor layers 36. The second semiconductor layers 36 may be in ohmic contact with the second electrode 42. The second electrode 42 is the other one of the electrodes for injecting the current into the light emitting layers 34. The second electrode 42 is made, for example, of an indium tin oxide (ITO).

### 1.2. Detailed Shape and Other Factors of Columnar Sections

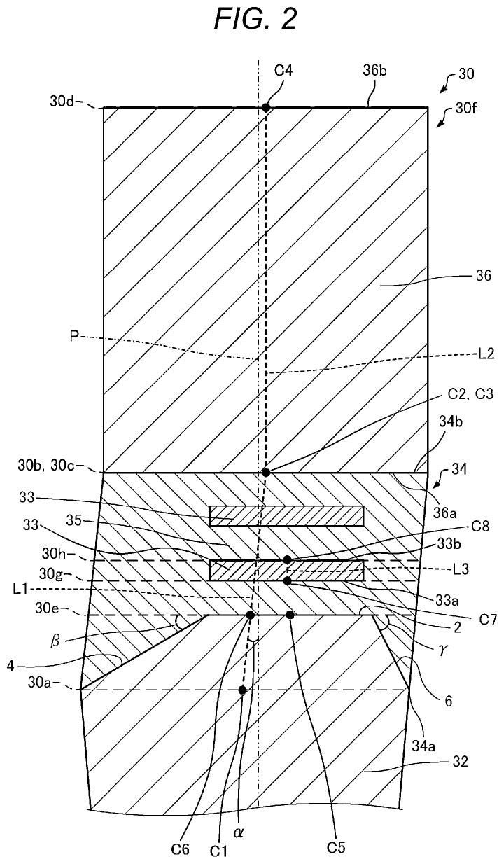

FIG. 2 is a cross-sectional view diagrammatically showing one of the columnar sections 30. The first semiconductor layer 32 has a c surface 2, as shown in FIG. 2. The c surface 2 is parallel to the substrate surface 12. The c surface 2 is perpendicular to the perpendicular P to the substrate surface 12. The first semiconductor layer 32, the light emitting layer 34, and the second semiconductor layer 36 are made, for example, of a group-III nitride semiconductor and each have a wurtzite crystal structure.

The light emitting layer 34 has a first end 34a facing the substrate 10 and a second end 34b facing away from the substrate 10. The second end 34b is the end facing the second electrode 42. A first cross section 30a and a second cross section 30b are each a cross section of the columnar section 30 taken along the in-plane directions. That is, the first cross section 30a and the second cross section 30b are each an in-plane-direction cross section of the columnar section 30. The first cross section 30a includes the first end 34a. The second cross section 30b includes the second end 34b. The second cross section 30b is a cross section that is part of the light emitting layer 34 and located at a position shifted from the first cross section 30a toward the side away from the substrate 10 in the lamination direction.

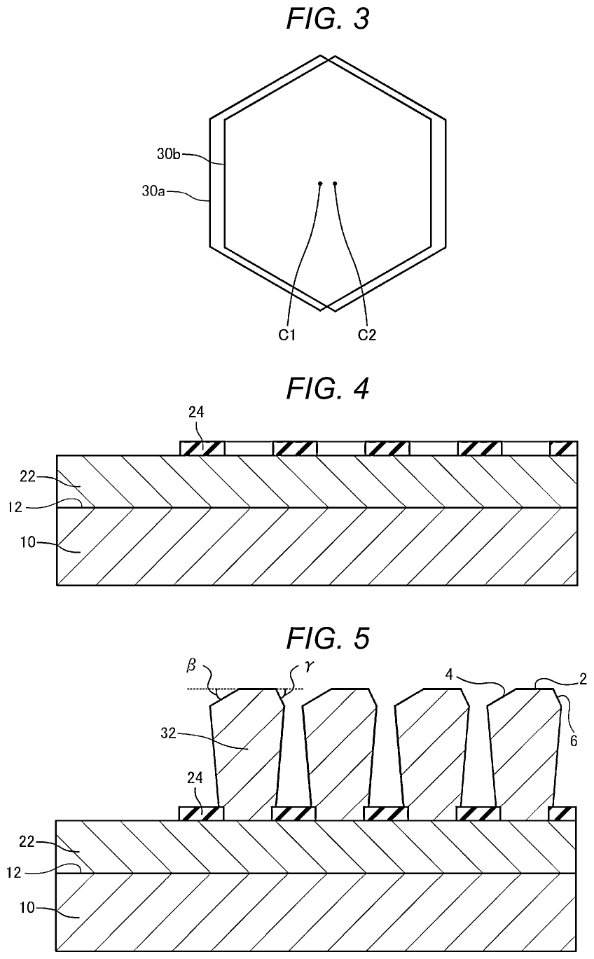

FIG. 3 diagrammatically shows the first cross section 30a and the second cross section 30b. In the plan view viewed in the lamination direction, the first cross section 30a does not partially coincide with the second cross section 30b, as shown in FIG. 3. In the plan view viewed in the lamination direction, the second cross section 30b does not partially coincide with the first cross section 30a. In the plan view viewed in the lamination direction, a center C1 of the first cross section 30a and a center C2 of the second cross section 30b are located in different positions. The center C1 is separate from the center C2. A straight line L1 passing through the center C1 of the first cross section 30a and the center C2 of the second cross section 30b inclines by an inclination angle α with respect to the perpendicular P to the substrate surface 12, as shown in FIG. 2. The columnar section 30 is bent at the first end 34a of the light emitting layer 34.

In the present embodiment, the shape of the first cross section 30a in the plan view viewed in the lamination direction is the same as the shape of the second cross section 30b in the plan view viewed in the lamination direction, but not necessarily, and the shape of the first cross section 30a may differ from the shape of the second cross section 30b. For example, the area of the first cross section 30a may differ from the area of the second cross section 30b in the plan view viewed in the lamination direction. For example, the area of the first cross section 30a may be smaller than the area of the second cross section 30b.

In the present embodiment, the second cross section 30b includes the second end 34b, but not necessarily. The second cross section 30b may be a cross section that is part of the light emitting layer 34 and located at a position shifted from the first cross section 30a toward the side away from the substrate 10 in the lamination direction with the position of the center C2 of the second cross section 30b being different from the position of the center C1 of the first cross section 30a in the plan view viewed in the lamination direction. That is, the second cross section 30b is a cross section of the columnar section 30 between the first end 34a and the second end 34b with the position of the center C2 of the second cross section 30b being different from the center C1 of the first cross section 30a in the plan view.

The second semiconductor layer 36 has a third end 36a facing the substrate 10 and a fourth end 36b facing away from the substrate 10. The fourth end 36b is the end facing the second electrode 42. A third cross section 30c and a fourth cross section 30d are each a cross section of the columnar section 30 taken along the in-plane directions. That is, the third cross section 30c and the fourth cross section 30d are each an in-plane-direction cross section of the columnar section 30. The third cross section 30c includes the third end 36a. The fourth cross section 30d includes the fourth end 36b. The inclination angle of a straight line L2 passing through a center C3 of the third cross section 30c and a center C4 of the fourth cross section 30d with respect to the perpendicular P is smaller than the inclination angle α of the straight line L1 with respect to the perpendicular P. In the illustrated example, the straight line L2 is parallel to the perpendicular P, and the inclination angle of the straight line L2 with respect to the perpendicular P is 0°. In the illustrated example, the third cross section 30c coincides with the second cross section 30b. The center C3 coincides with the center C2 in the plan view. The columnar section 30 is bent at the second end 34b of the light emitting layer 34. The light emitting layer 34 of the columnar section 30 inclines with respect to the perpendicular P.

A fifth cross section 30e is a cross section of the columnar section 30 taken along the in-plane directions. That is, the fifth cross section 30e is an in-plane-direction cross section of the columnar section 30. The fifth cross section 30e includes a center C5 of the c surface 2. In the plan view viewed in the lamination direction, the center C5 of the c surface 2 is shifted from a center C6 of the fifth cross section 30e of the columnar section 30. In other words, the center C1 is separate from the center C2. The position of the center C5 differs from the position of the center C6.

A sixth cross section 30f is a cross section of the columnar section 30 taken along the lamination direction. That is, the sixth cross section 30f is a lamination-direction cross section of the columnar section 30. The sixth cross section 30f includes the center C5 of the c surface 2. The sixth cross section 30f is the cross section of the columnar section 30 shown in FIG. 2. In the sixth cross section 30f, the first semiconductor layer 32 has a first facet surface 4 and a second facet surface 6. The facet surfaces 4 and 6 are coupled to the c surface 2. The facet surfaces 4 and 6 incline with respect to the c surface 2. The second facet surface 6 differs from the first facet surface 4 in terms of the inclination angle with respect to the c surface 2. In the illustrated example, an inclination angle β of the first facet surface 4 with respect to the c surface 2 is smaller than an inclination angle γ of the second facet surface 6 with respect to the c surface 2. The first facet surface 4 and the second facet surface 6 are continuous with each other in the plan view viewed in the lamination direction.

The well layers 33 of the light emitting layer 34 each have a fifth end 33a facing the substrate 10 and a six end 33b facing away from the substrate 10. The sixth end 33b is the end facing the second electrode 42. A seventh cross section 30g and an eighth cross section 30h are each a cross section of the columnar section 30 taken along the in-plane directions. That is, the seventh cross section 30g and the eighth cross section 30h are each an in-plane-direction cross section of the columnar section 30. The seventh cross section 30g includes the fifth end 33a. The eighth cross section 30h includes the sixth end 33b. The inclination angle of a straight line L3 passing through a center C7 of the seventh cross section 30g and a center C8 of the eighth cross section 30h with respect to the perpendicular P is smaller than the inclination angle α of the straight line L1 with respect to the perpendicular P. In the illustrated example, the straight line L3 is parallel to the perpendicular P, and the inclination angle of the straight line L3 with respect to the perpendicular P is 0°.

### 1.3. Effects and Advantages

In the light emitting apparatus 100, the light emitting layers 34 each have the first end 34a facing the substrate 10 and the second end 34b facing away from the substrate 10, the first cross section 30a of each of the columnar sections 30 taken along the in-plane directions includes the first end 34a, and the second cross section 30b of each of the columnar sections 30 taken along the in-plane directions is a cross section that is part of the light emitting layer 34 and located at a position shifted from the first cross section 30a toward the side away from the substrate 10 in the lamination direction. In the plan view viewed in the lamination direction, the center C1 of the first cross section 30a and the center C2 of the second cross section 30b are located in different positions. Therefore, in the light emitting apparatus 100, a light confinement coefficient can be reduced and a radiation coefficient can be increased as compared, for example, with a case where the position of the center of the first cross section 30a coincides with the position of the center of the second cross section 30b. The intensity of the emitted light can thus be increased.

In the light emitting apparatus 100, the second cross section 30b includes the second end 34b, and in the plan view viewed in the lamination direction, the first cross section 30a does not partially coincide with the second cross section 30b, and the second cross section 30b does not partially coincide with the first cross section 30a. Therefore, in the light emitting apparatus 100, the light confinement coefficient can be reduced and the radiation coefficient can be increased as compared, for example, with a case where the first cross section 30a fully coincides with the second cross section 30b in the plan view. The intensity of the emitted light can thus be increased.

In the light emitting apparatus 100, the columnar sections 30 each include the first semiconductor layer 32 and the second semiconductor layer 36 having a conductivity type different from that of the first semiconductor layer 32, with the light emitting layer 34 provided between the first semiconductor layer 32 and the second semiconductor layer 36, the first semiconductor layer 32 provided between the substrate 10 and the light emitting layer 34. Therefore, in the light emitting apparatus 100, current can be injected into the light emitting layer 34 via the first semiconductor layer 32 and the second semiconductor layer 36.

The light emitting apparatus 100 includes the second electrode 42 provided on the opposite side of the laminated structure 20 from the substrate 10, and the second semiconductor layer 36 has the third end 36a facing the substrate 10 and the fourth end 36b facing the second electrode 42. The inclination angle of the straight line L2, which passes through the center C3 of the third cross section 30c of the columnar section 30 taken along the in-plane directions and including the third end 36a and the center C4 of the fourth cross section 30d of the columnar section 30 taken along the in-plane directions and including the fourth end 36b, with respect to the perpendicular P to the substrate surface 12 is smaller than the inclination angle α of the straight line L1, which passes through the center C1 of the first cross section 30a and the center C2 of the second cross section 30b, with respect to the perpendicular P to the substrate surface 12. Therefore, in the light emitting apparatus 100, the flatness of the second electrode 42 can be increased as compared with a case where the inclination angle of the straight line L2 with respect to the perpendicular P is greater than the inclination angle α. As a result, the current can be uniformly injected into the light emitting layers 34.

In the light emitting apparatus 100, the first semiconductor layers 32 each have the c surface 2, and in the plan view viewed in the lamination direction, the center C5 of the c surface 2 is shifted from the center C6 of the fifth cross section 30e of the columnar section 30 taken along the in-plane directions and including the center C5 of the c surface 2. Therefore, in the light emitting apparatus 100, the columnar sections 30 can each be bent at the first end 34a of the light emitting layer 34.

In the light emitting apparatus 100, in the sixth cross section 30f of each of the columnar sections 30 taken along the lamination direction and including the center C5 of the c surface 2, the first semiconductor layer 32 has the first facet surface 4 and the second facet surface 6 different from the first facet surface 4 in terms of inclination angle with respect to the c surface 2. Therefore, in the light emitting apparatus 100, the columnar sections 30 can each be bent at the first end 34a of the light emitting layer 34.

In the light emitting apparatus 100, the light emitting layers 34 each include the well layers 33 and the barrier layers 35, and the well layers 33 each have the fifth end 33a facing the substrate 10 and the sixth end 33b facing away from the substrate 10. In each of the columnar sections 30, the inclination angle of the straight line L3, which passes through the center C7 of the seventh cross section 30g taken along the in-plane directions and including the fifth end 33a and the center C8 of the eighth cross section 30h of the columnar section 30 taken along the in-plane directions and including the sixth end 33b, with respect to the perpendicular P to the substrate surface 12 is smaller than the inclination angle α of the straight line L1, which passes through the center C1 of the first cross section 30a and the center C2 of the second cross section 30b, with respect to the perpendicular P to the substrate surface 12. Therefore, in the light emitting apparatus 100, the uniformity of strain induced in the well layers 33 can be increased as compared with a case where the inclination angle of the straight line L3 with respect to the perpendicular P is greater than the inclination angle α. Variation in the wavelength of the emitted light can thus be suppressed.

### 2. Method for Manufacturing Light Emitting Apparatus

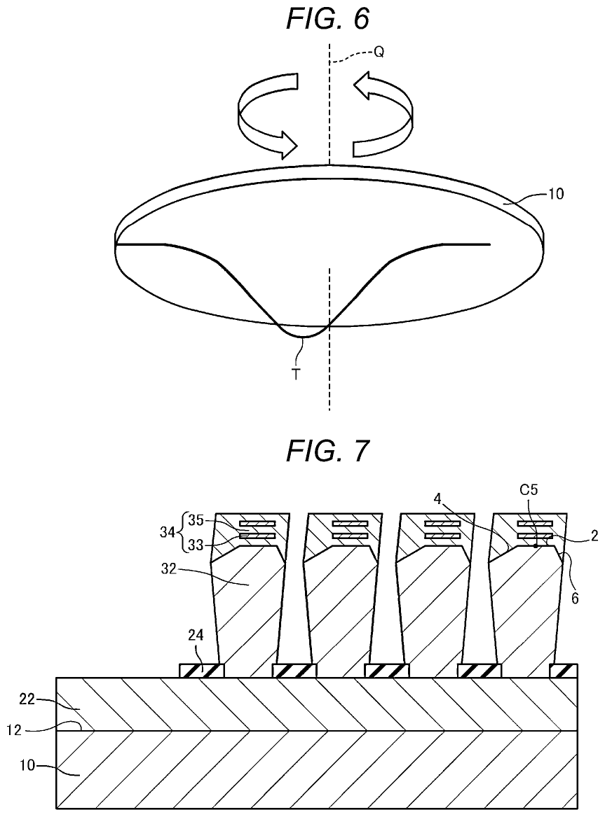

A method for manufacturing the light emitting apparatus 100 according to the present embodiment will next be described with reference to the drawings. A method for manufacturing the light emitting apparatus 100 according to the present embodiment will next be described with reference to the drawings. FIGS. 4 and 5 are cross-sectional views each diagrammatically showing one of the steps of manufacturing the light emitting apparatus 100 according to the present embodiment. FIG. 6 is a perspective view diagrammatically showing one of the steps of manufacturing the light emitting apparatus 100 according to the present embodiment. FIG. 7 is a cross-sectional view diagrammatically showing one of the steps of manufacturing the light emitting apparatus 100 according to the present embodiment.

The buffer layer 22 is epitaxially grown on the substrate 10, as shown in FIG. 4. Examples of the epitaxial growth method may include molecular beam epitaxy (MBE) and other physical deposition methods.

The mask layer 24 is then formed on the buffer layer 22. The mask layer 24 is formed, for example, by film formation using electron beam vapor deposition or sputtering, and patterning. The patterning is performed, for example, by photolithography and etching.

The mask layer 24 is used as a mask to epitaxially grow the first semiconductor layers 32 on the buffer layers 22, as shown in FIG. 5. Examples of the epitaxial growth method may include MBE and other physical deposition methods.

The growth of the first semiconductor layers 32 is performed by rotating the substrate 10 on which the buffer layer 22 and mask layer 24 have been formed around an axis of rotation Q with the axis of rotation Q shifted from a peak position T, where the intensity of the molecular beam peaks, as shown in FIG. 6. The MBE method, in which a target is irradiated with the molecular beam in an ultrahigh vacuum, can control the position irradiated with the molecular beam and the intensity distribution of the molecular beam. The radiation position and intensity distribution control effect cannot be achieved by metal organic chemical vapor deposition (MOCVD) or other vapor phase growth methods.

The first semiconductor layers 32 each having the c surface 2 and the facet surfaces 4 and 6 having the inclination angles β and γ different from each other can thus be grown, as shown in FIG. 5.

The light emitting layers 34 are epitaxially grown on the first semiconductor layers 32, as shown in FIG. 7. Examples of the epitaxial growth method may include MBE and other physical deposition methods. When the light emitting layers 34 contain InGaN, the InGaN concentrates in the vicinity of the center C5 of the c surface 2, where the amount of induced strain is small. The light emitting layers 34 therefore grow in a direction that inclines with respect to the substrate surface 12. The light emitting layers 34 are grown, for example, with the axis of rotation Q aligned with the peak position T, where the intensity of the molecular beam peaks.

The second semiconductor layers 36 are epitaxially grown on the light emitting layers 34, as shown in FIG. 1. Examples of the epitaxial growth method may include MBE and other physical deposition methods. The second semiconductor layers 36 are grown, for example, with the axis of rotation Q aligned with the peak position T, where the intensity of the molecular beam peaks. For example, the second semiconductor layers 36 contain no InGaN layer and is therefore unlikely to incline with respect to the substrate surface 12. The laminated structure 20 including the columnar sections 30 can be formed by carrying out the steps described above.

Thereafter, the first electrode 40 is formed on the buffer layer 22, and the second electrode 42 is formed on the second semiconductor layers 36. The first electrode 40 and the second electrode 42 are formed, for example, by vacuum vapor deposition. The first electrode 40 and the second electrode 42 are not necessarily formed in a specific order. The substrate 10 is then cut into a predetermined shape.

The light emitting apparatus 100 can be manufactured by carrying out the steps described above.

### 3. Projector

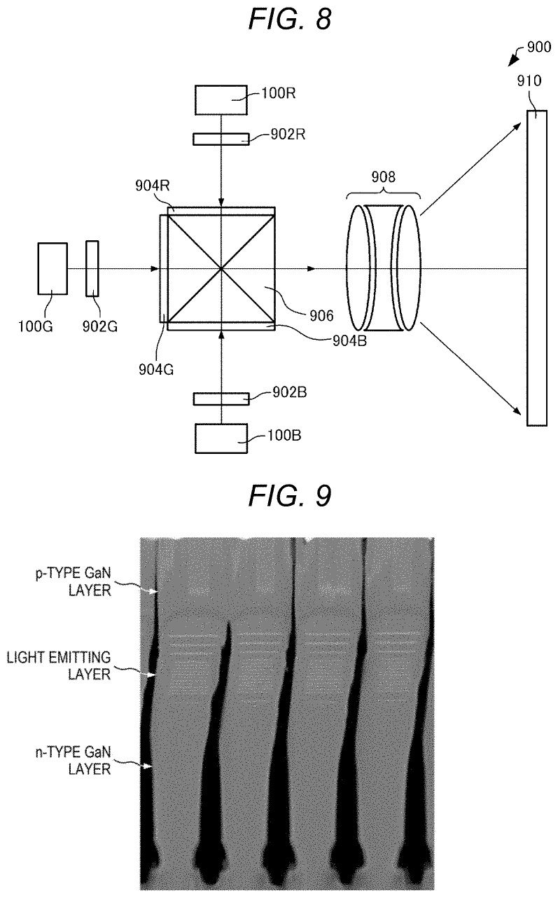

A projector according to the present embodiment will next be described with reference to the drawings. FIG. 8 diagrammatically shows a projector 900 according to the present embodiment.

The projector 900 includes, for example, the light emitting apparatus 100 as a light source.

The projector 900 includes an enclosure that is not shown, and a red light source 100R, a green light source 100G, and a blue light source 100B, which are provided in the enclosure and output red light, green light, and blue light, respectively. In FIG. 8, the red light source 100R, the green light source 100G, and the blue light source 100B are simplified for convenience.

The projector 900 further includes a first optical element 902R, a second optical element 902G, a third optical element 902B, a first light modulator 904R, a second light modulator 904G, a third light modulator 904B, and a projection apparatus 908, which are provided in the enclosure. The first light modulator 904R, the second light modulator 904G, and the third light modulator 904B are each, for example, a transmissive liquid crystal light valve. The projection apparatus 908 is, for example, a projection lens.

The light outputted from the red light source 100R enters the first optical element 902R. The first optical element 902R collects the light outputted from the red light source 100R. The first optical element 902R may have another function in addition to the light collection function. The same holds true for the second optical element 902G and the third optical element 902B, which will be described later.

The light collected by the first optical element 902R is incident on the first light modulator 904R. The first light modulator 904R modulates the light incident thereon in accordance with image information. The projection apparatus 908 then enlarges an image formed by the first light modulator 904R and projects the enlarged image on a screen 910.

The light outputted from the green light source 100G enters the second optical element 902G. The second optical element 902G collects the light outputted from the green light source 100G.

The light collected by the second optical element 902G is incident on the second light modulator 904G. The second light modulator 904G modulates the light incident thereon in accordance with image information. The projection apparatus 908 then enlarges an image formed by the second light modulator 904G and projects the enlarged image on the screen 910.

The light outputted from the blue light source 100B enters the third optical element 902B. The third optical element 902B collects the light outputted from the blue light source 100B.

The light collected by the third optical element 902B is incident on the third light modulator 904B. The third light modulator 904B modulates the light incident thereon in accordance with image information. The projection apparatus 908 then enlarges an image formed by the third light modulator 904B and projects the enlarged image on the screen 910.

The projector 900 can further include a cross dichroic prism 906, which combines the light outputted from the first light modulator 904R, the light outputted from the second light modulator 904G, and the light outputted from the third light modulator 904B with one another and guides the combined light to the projection apparatus 908.

The red light modulated by the first light modulator 904R, the green light modulated by the second light modulator 904G, and the blue light modulated by the third light modulator 904B enter the cross dichroic prism 906. The cross dichroic prism 906 is formed by bonding four right-angled prisms to each other, and a dielectric multilayer film that reflects the red light and a dielectric multilayer film that reflects the blue light are disposed at the inner surfaces of the combined prisms. The dielectric multilayer films combine the red light, the green light, and the blue light with one another to form light representing a color image. The combined light is then projected by the projection apparatus 908 on the screen 910, whereby an enlarged image is displayed.

The red light source 100R, the green light source 100G, and the blue light source 100B may instead directly form images in a configuration in which none of the first light modulator 904R, the second light modulator 904G, and the third light modulator 904B is used but the light emitting apparatuses 100 corresponding to the light sources are controlled as the pixels of the images in accordance with the image information. The projection apparatus 908 may then enlarge the images formed by the red light source 100R, the green light source 100G, and the blue light source 100B and project the enlarged images on the screen 910.

In the example described above, transmissive liquid crystal light valves are used as the light modulators, and light valves based not on liquid crystal materials or reflective light valves may be used. Examples of such light valves may include reflective liquid crystal light valves and digital micromirror devices. The configuration of the projection apparatus is changed as appropriate in accordance with the type of the light valves used in the projector.

The present disclosure is also applicable to a light source apparatus of a scanning-type image display apparatus including a light source and a scanner that is an image formation apparatus that displays an image having a desired size on a display surface by scanning the screen with the light from the light source.

The light emitting apparatus according to the embodiment described above can be used in other applications in addition to a projector. Examples of the applications other than a projector may include an indoor or outdoor illuminator, a display, a laser printer, a scanner, an in-vehicle light, a sensing instrument using light, and a light source of a communication instrument.

### 4. Experimental Example

Columnar sections each including an n-type GaN layer, a light emitting layer including an i-type InGaN layer and an i-type GaN layer, and a p-type GaN layer were epitaxially grown on a substrate by using MBE. The n-type GaN layer was grown with the axis of rotation of the substrate shifted from the peak position where the intensity of the molecular beam peaks.

FIG. 9 shows a cross-sectional TEM (transmission electron microscope) image of some of the columnar sections formed as described above. FIG. 9 shows that the light emitting layers grew in a direction that inclines with respect to the substrate surface.

The embodiment and the variations described above are presented by way of example, and the present disclosure is not limited thereto. For example, the embodiment and each of the variations can be combined with each other as appropriate.

The present disclosure encompasses substantially the same configuration as the configuration described in the embodiment, for example, a configuration having the same function, using the same method, and providing the same result or a configuration having the same purpose and providing the same effect. Furthermore, the present disclosure encompasses a configuration in which an inessential portion of the configuration described in the embodiment is replaced. Moreover, the present disclosure encompasses a configuration that provides the same effects and advantages as those provided by the configuration described in the embodiment or a configuration that can achieve the same purpose as that achieved by the configuration described in the embodiment. Furthermore, the present disclosure encompasses a configuration in which a known technology is added to the configuration described in the embodiment.

The following contents are derived from the embodiment and the variations described above.

A light emitting apparatus according to an aspect includes a substrate and a laminated structure provided at a substrate surface of the substrate and including a plurality of columnar sections. The columnar sections each include a light emitting layer. The light emitting layer has a first end facing the substrate and a second end facing away from the substrate. A first cross section of each of the columnar sections taken along the directions perpendicular to the lamination direction of the laminated structure includes the first end. A second cross section of each of the columnar sections taken along the directions perpendicular to the lamination direction is a cross section that is part of the light emitting layer and located at a position shifted from the first cross section toward the side away from the substrate in the lamination direction. In the plan view viewed in the lamination direction, the position of the center of the first cross section differs from the position of the center of the second cross section.

According to the light emitting apparatus, the intensity of the emitted light can be increased.

In the light emitting apparatus according to the aspect, the second cross section may include the second end.

In the light emitting apparatus according to the aspect, in the plan view viewed in the lamination direction, the first cross section may not partially coincide with the second cross section, and the second cross section may not partially coincide with the first cross section.

According to the light emitting apparatus, the intensity of the emitted light can be increased.

In the light emitting apparatus according to the aspect, the columnar sections may each include a first semiconductor layer, and a second semiconductor layer different from the first semiconductor layer in terms of conductivity type. The light emitting layer may be provided between the first semiconductor layer and the second semiconductor layer. The first semiconductor layer may be provided between the substrate and the light emitting layer.

According to the light emitting apparatus, current can be injected into the light emitting layer via the first semiconductor layer and the second semiconductor layer.

In the light emitting apparatus according to the aspect, the light emitting apparatus may include an electrode provided on the opposite side of the laminated structure from the substrate. The second semiconductor layers may each have a third end facing the substrate and a fourth end facing the electrode. The inclination angle of a straight line with respect to a perpendicular to the substrate surface, the straight line passing through the center of a third cross section of each of the columnar sections taken along the perpendicular directions and including the third end and the center of a fourth cross section of the columnar section taken along the perpendicular directions and including the fourth end, may be smaller than the inclination angle of a straight line with respect to the perpendicular to the substrate surface, the straight line passing through the center of the first cross section and the center of the second cross section.

According to the light emitting apparatus, the flatness of the electrode can be increased.

In the light emitting apparatus according to the aspect, the first semiconductor layers may each have a c surface. In the plan view viewed in the lamination direction, the center of the c surface may be shifted from the center of a fifth cross section of each of the columnar sections taken along the perpendicular directions and including the center of the c surface.

According to the light emitting apparatus, the columnar sections can each be bent at the first end of the light emitting layer.

In the light emitting apparatus according to the aspect, in a sixth cross section of each of the columnar sections taken along the lamination direction and including the center of the c surface, the first semiconductor layer may have a first facet surface and a second facet surface different from the first facet surface in terms of the inclination angle with respect to the c surface.

According to the light emitting apparatus, the columnar sections can each be bent at the first end of the light emitting layer.

In the light emitting apparatus according to the aspect, the light emitting layers may each include a well layer and a barrier layer. The well layer may have a fifth end facing the substrate and a sixth end facing away from the substrate. The inclination angle of a straight line with respect to the perpendicular to the substrate surface, the straight line passing through the center of a seventh cross section of each of the columnar sections taken along the perpendicular directions and including the fifth end and the center of an eighth cross section of the columnar section taken along the perpendicular directions and including the sixth end, may be smaller than the inclination angle of the straight line with respect to the perpendicular to the substrate surface, the straight line passing through the center of the first cross section and the center of the second cross section.

According to the light emitting apparatus, the uniformity of strain induced in the well layer can be increased.

A projector according to another aspect of the present disclosure includes the light emitting apparatus according to the aspect described above.

What is claimed is:

1. A light emitting apparatus comprising:
a substrate; and
a laminated structure provided at a substrate surface of the substrate and including a plurality of columnar sections,
wherein the columnar sections each include a light emitting layer,
the light emitting layer has a first end facing the substrate and a second end facing away from the substrate,
a first cross section of each of the columnar sections taken along directions perpendicular to a lamination direction of the laminated structure includes the first end,
a second cross section of each of the columnar sections taken along the directions perpendicular to the lamination direction is a cross section that is part of the light emitting layer and located at a position shifted from the first cross section toward the side away from the substrate in the lamination direction, and
in a plan view viewed in the lamination direction, a position of a center of the first cross section differs from a position of a center of the second cross section.

2. The light emitting apparatus according to claim 1,
wherein the second cross section includes the second end.

3. The light emitting apparatus according to claim 1,
wherein in the plan view viewed in the lamination direction,
the first cross section does not partially coincide with the second cross section, and
the second cross section does not partially coincide with the first cross section.

4. The light emitting apparatus according to claim 1,
wherein the columnar sections each include
a first semiconductor layer, and
a second semiconductor layer different from the first semiconductor layer in terms of conductivity type,
the light emitting layer is provided between the first semiconductor layer and the second semiconductor layer, and
the first semiconductor layer is provided between the substrate and the light emitting layer.

5. The light emitting apparatus according to claim 4,
further comprising an electrode provided on an opposite side of the laminated structure from the substrate,
wherein the second semiconductor layers each have a third end facing the substrate and a fourth end facing the electrode, and
an inclination angle of a straight line with respect to a perpendicular to the substrate surface, the straight line passing through a center of a third cross section of each of the columnar sections taken along the perpendicular directions and including the third end and a center of a fourth cross section of the columnar section taken along the perpendicular directions and including the fourth end, is smaller than an inclination angle of a straight line with respect to the perpendicular to the substrate surface, the straight line passing through the center of the first cross section and the center of the second cross section.

6. The light emitting apparatus according to claim 4,
wherein the first semiconductor layers each have a c surface, and
in the plan view viewed in the lamination direction, a center of the c surface is shifted from a center of a fifth cross section of each of the columnar sections taken along the perpendicular directions and including the center of the c surface.

7. The light emitting apparatus according to claim 6,
wherein in a sixth cross section of each of the columnar sections taken along the lamination direction and including the center of the c surface,
the first semiconductor layer has
a first facet surface, and
a second facet surface different from the first facet surface in terms of the inclination angle with respect to the c surface.

8. The light emitting apparatus according to claim 1,
wherein the light emitting layers each include a well layer and a barrier layer,
the well layer has a fifth end facing the substrate and a sixth end facing away from the substrate, and
an inclination angle of a straight line with respect to a perpendicular to the substrate surface, the straight line passing through a center of a seventh cross section of each of the columnar sections taken along the perpendicular directions and including the fifth end and a center of an eighth cross section of the columnar section taken along the perpendicular directions and including the sixth end, is smaller than an inclination angle of a straight line with respect to the perpendicular to the substrate surface, the straight line passing through the center of the first cross section and the center of the second cross section.

9. A projector comprising the light emitting apparatus according to claim 1.
